(19) United States
(12) Patent Application Publication
(10) Pub. No.: US 2025/0362620 A1
(43) Pub. Date: Nov. 27, 2025

(54) TARGET SUPPLY DEVICE, EXTREME ULTRAVIOLET LIGHT GENERATION APPARATUS, AND ELECTRONIC DEVICE MANUFACTURING METHOD

(71) Applicant: Gigaphoton Inc., Tochigi (JP)

(72) Inventors: Masaru ENDO, Oyama-shi (JP); Fumio IWAMOTO, Oyama-shi (JP); Masaki NAKANO, Oyama-shi (JP)

(73) Assignee: Gigaphoton Inc., Tochigi (JP)

(21) Appl. No.: 19/173,277

(22) Filed: Apr. 8, 2025

(30) Foreign Application Priority Data
May 21, 2024 (JP) 2024-082836

(51) Int. Cl. G03F 7/00; H01L 21/67

(52) U.S. Cl. CPC G03F 7/70858; G03F 7/70033; G03F 7/70525; H01L 21/67017

(57) ABSTRACT

A target supply device includes a tank main body portion containing a target substance; an output portion outputting the target substance; an intermediate portion located between the tank main body portion and the output portion; a first main heater heating the tank main body portion; a first sub-heater heating the output portion; an intermediate portion heater heating the intermediate portion; and a temperature control processor configured to perform temperature lowering control of the first main heater, the first sub-heater, and the intermediate portion heater after output of the target substance is stopped. The temperature control processor sets, in the temperature lowering control, a temperature of the intermediate portion heater to a temperature lower than a melting point of the target substance while setting each of a temperature of the first main heater and a temperature of the first sub-heater to a temperature higher than the melting point.

### CROSS-REFERENCE TO RELATED APPLICATIONS

The present application claims the benefit of Japanese Patent Application No. 2024/082836, filed on May 21, 2024, the entire contents of which are hereby incorporated by reference.

### BACKGROUND

### 1. Technical Field

The present disclosure relates to a target supply device, an extreme ultraviolet light generation apparatus, and an electronic device manufacturing method.

### 2. Related Art

Recently, miniaturization of a transfer pattern in optical lithography of a semiconductor process has been rapidly proceeding along with miniaturization of the semiconductor process. In the next generation, microfabrication at 10 nm or less will be required. Therefore, it is expected to develop a semiconductor exposure apparatus that combines an apparatus for generating extreme ultraviolet (EUV) light having a wavelength of about 13 nm with a reduced projection reflection optical system.

As the extreme ultraviolet light generation apparatus, a laser produced plasma (LPP) type apparatus using plasma generated by irradiating a target substance with laser light has been developed.

### LIST OF DOCUMENTS

### Patent Documents

Patent Document 1: US patent application Publication No. 2013/209077
Patent Document 2: US patent application Publication No. 2014/042653

### SUMMARY

A target supply device according to an aspect of the present disclosure includes a tank main body portion configured to contain a target substance; an output portion configured to output the target substance; an intermediate portion located between the tank main body portion and the output portion; a first main heater configured to heat the tank main body portion; a first sub-heater configured to heat the output portion; an intermediate portion heater configured to heat the intermediate portion; and a temperature control processor configured to perform temperature lowering control of the first main heater, the first sub-heater, and the intermediate portion heater after output of the target substance is stopped. The temperature control processor sets, in the temperature lowering control, a temperature of the intermediate portion heater to a temperature lower than a melting point of the target substance while setting each of a temperature of the first main heater and a temperature of the first sub-heater to a temperature higher than the melting point of the target substance.

An extreme ultraviolet light generation apparatus according to an aspect of the present disclosure includes a chamber in which a target substance supplied to an internal space thereof is irradiated with laser light to generate extreme ultraviolet light, and a target supply device configured to supply the target substance into the chamber. Here, the target supply device includes a tank main body portion configured to contain the target substance; an output portion configured to output the target substance; an intermediate portion located between the tank main body portion and the output portion; a first main heater configured to heat the tank main body portion; a first sub-heater configured to heat the output portion; an intermediate portion heater configured to heat the intermediate portion; and a temperature control processor configured to perform temperature lowering control of the first main heater, the first sub-heater, and the intermediate portion heater after output of the target substance is stopped. The temperature control processor sets, in the temperature lowering control, a temperature of the intermediate portion heater to a temperature lower than a melting point of the target substance while setting each of a temperature of the first main heater and a temperature of the first sub-heater to a temperature higher than the melting point of the target substance.

An electronic device manufacturing method according to an aspect of the present disclosure includes generating extreme ultraviolet light using an extreme ultraviolet light generation apparatus, outputting the extreme ultraviolet light to an exposure apparatus, and exposing a photosensitive substrate to the extreme ultraviolet light in the exposure apparatus to manufacture an electronic device. Here, the extreme ultraviolet light generation apparatus including a chamber in which a target substance supplied to an internal space thereof is irradiated with laser light to generate the extreme ultraviolet light, and a target supply device configured to supply the target substance into the chamber. The target supply device includes a tank main body portion configured to contain the target substance; an output portion configured to output the target substance; an intermediate portion located between the tank main body portion and the output portion; a first main heater configured to heat the tank main body portion; a first sub-heater configured to heat the output portion; an intermediate portion heater configured to heat the intermediate portion; and a temperature control processor configured to perform temperature lowering control of the first main heater, the first sub-heater, and the intermediate portion heater after output of the target substance is stopped. The temperature control processor sets, in the temperature lowering control, a temperature of the intermediate portion heater to a temperature lower than a melting point of the target substance while setting each of a temperature of the first main heater and a temperature of the first sub-heater to a temperature higher than the melting point of the target substance.

### BRIEF DESCRIPTION OF THE DRAWINGS

Embodiments of the present disclosure will be described below merely as examples with reference to the accompanying drawings.

FIG. 1 is a schematic view showing a schematic configuration example of an entire electronic device manufacturing apparatus.

FIG. 2 is a schematic view showing a schematic configuration example of an entire extreme ultraviolet light generation apparatus.

FIG. 3 is a schematic view showing a schematic configuration of a target supply device of a comparative example.

FIG. 4 is a graph showing a state of the temperature of each heater of the target supply device of the comparative example.

FIG. 5 is a schematic view showing a deviation of solidification shrinkage of a target substance in the comparative example.

FIG. 6 is a flowchart showing operation of a control unit in a first embodiment.

FIG. 7 is a graph showing a state of the temperature of each heater of the target supply device of the first embodiment.

FIG. 8 is a schematic view showing a state when cooling of an intermediate portion is started in the first embodiment.

FIG. 9 is a schematic view showing a state when cooling of the intermediate portion is advanced to some extent in the first embodiment.

FIG. 10 is a schematic view showing a state when the target substance in the intermediate portion is solidified in the first embodiment.

FIG. 11 is a schematic view showing a schematic configuration of the target supply device of a second embodiment.

FIG. 12 is a flowchart showing operation of the control unit in the second embodiment.

FIG. 13 is a graph showing a state of the temperature of each heater of the target supply device of the second embodiment.

### DESCRIPTION OF EMBODIMENTS

1. Overview
2. Description of electronic device manufacturing apparatus used in exposure process for electronic device
3. Description of extreme ultraviolet light generation system
4. Description of target supply device of comparative example
   4.1 Configuration
   4.2 Operation
5. Problem
6. First Embodiment
   6.1 Operation of extreme ultraviolet light generation apparatus of first embodiment
   6.2 Effect
7. Second Embodiment
   7.1 Configuration of extreme ultraviolet light generation apparatus of second embodiment
   7.2 Operation of extreme ultraviolet light generation apparatus of second embodiment
   7.3 Effect

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Overview

Embodiments of the present disclosure relate to an extreme ultraviolet light generation apparatus generating light having a wavelength region of extreme ultraviolet (EUV) light, and an electronic device manufacturing apparatus.

### 2. Description of Electronic Device Manufacturing Apparatus Used in Exposure Process for Electronic Device

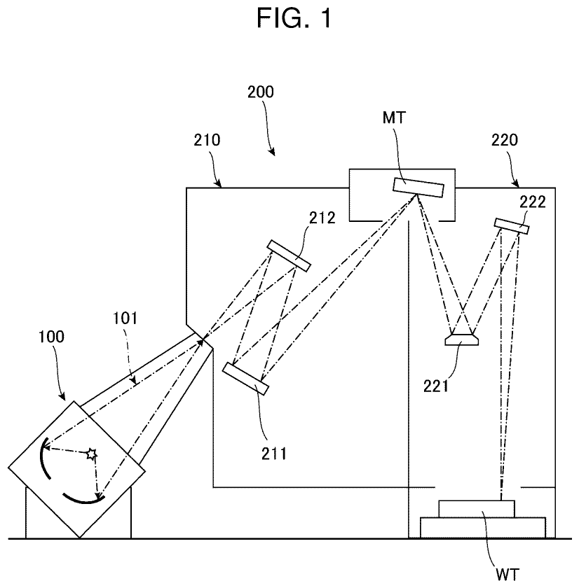

FIG. 1 is a schematic view showing a schematic configuration example of an entire electronic device manufacturing apparatus used in an exposure process for an electronic device. As shown in FIG. 1, the manufacturing apparatus used in the exposure process includes an extreme ultraviolet light generation apparatus 100 and an exposure apparatus 200. The exposure apparatus 200 includes an illumination optical system 210 including a plurality of mirrors 211, 212, 213 and a projection optical system 220. The illumination optical system 210 illuminates a reticle pattern of a reticle stage RT with laser light incident from the extreme ultraviolet light generation apparatus 100. The projection optical system 220 causes the laser light transmitted through the reticle to be imaged as being reduced and projected on a workpiece (not shown) arranged on a workpiece table WT. The workpiece is a photosensitive substrate such as a semiconductor wafer on which photoresist is applied. The exposure apparatus 200 synchronously translates the reticle stage RT and the workpiece table WT to expose the workpiece to the laser light reflecting the reticle pattern. Through the exposure process as described above, a device pattern is transferred onto the semiconductor wafer, thereby a semiconductor device, which is the electronic device, can be manufactured.

### 3. Description of Extreme Ultraviolet Light Generation System

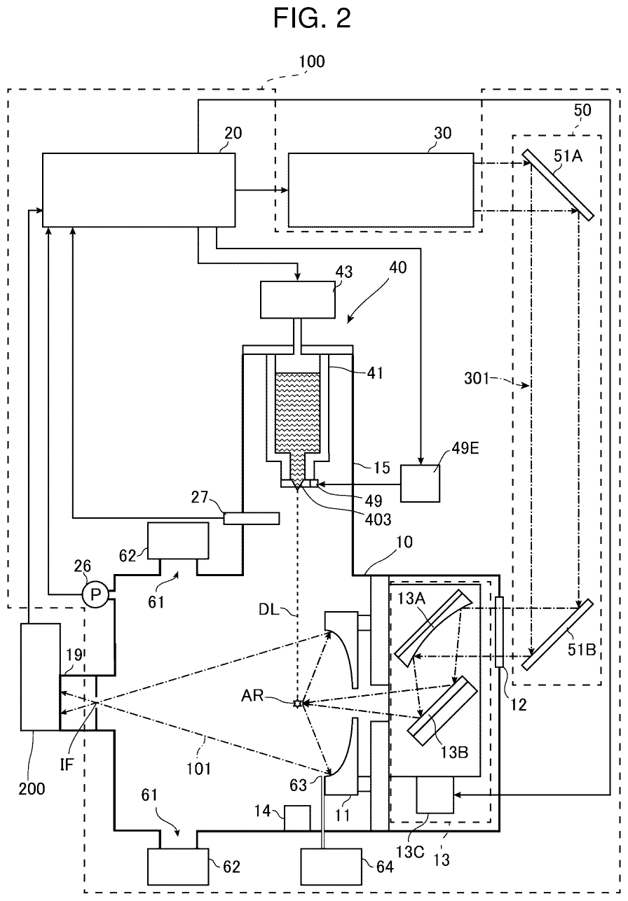

FIG. 2 schematically shows the configuration of an LPP extreme ultraviolet light generation system. The extreme ultraviolet light generation apparatus 100 is used together with a laser device 30. In the present disclosure, a system including the extreme ultraviolet light generation apparatus 100 and the laser device 30 is referred to as the extreme ultraviolet light generation system. The extreme ultraviolet light generation apparatus 100 includes a chamber 10 and a target supply device 40. The chamber 10 is a sealable container.

A through hole is formed in a wall of the chamber 10. The through hole is blocked by a window 12 through which pulse laser light 301 output from the laser device 30 passes. An extreme ultraviolet light concentrating mirror 11 having a spheroidal reflection surface is arranged in the chamber 10. The extreme ultraviolet light concentrating mirror 11 has first and second focal points. A multilayer reflection film in which, for example, molybdenum and silicon are alternately stacked is formed on a surface of the extreme ultraviolet light concentrating mirror 11. The extreme ultraviolet light concentrating mirror 11 may be arranged so that the first focal point is located in a plasma generation region AR and the second focal point is located at an intermediate focal point IF. A through hole is formed at the center of the extreme ultraviolet light concentrating mirror 11, and the pulse laser light 301 passes through the through hole.

The target supply device 40 includes a tank 41. The target supply device 40 is configured to supply the droplet DL to the internal space of the chamber 10, and is mounted, for example, so as to penetrate a wall of a sub-chamber 15. The droplet DL, which is also called a target, is supplied from the target supply device 40.

The tank 41 stores therein a target substance which becomes the droplet DL. The target substance may include, but is not limited to, any one of tin, terbium, gadolinium, lithium, and xenon, or a combination of any two or more thereof. The inside of the tank 41 communicates, through a pipe, with a pressure regulator 43 which adjusts gas pressure. The pressure regulator 43 is connected to the processor 20.

The processor of the present disclosure is a processing device including a storage device in which a control program is stored and a central processing unit (CPU) that executes the control program. The processor is specifically configured or programmed to perform various processes included in the present disclosure.

The nozzle 403 is attached to the tank 41. The nozzle 403 is an output portion that outputs the target substance. A piezoelectric element 49 is attached to the nozzle 403. The piezoelectric element 49 is connected to a piezoelectric power source 49E and is driven by a voltage applied from the piezoelectric power source 49E. The piezoelectric power source 49E is electrically connected to the processor 20. The target substance output from the nozzle 403 is formed into the droplet DL through operation of the piezoelectric element 49.

The chamber 10 is provided with a target collector 14. The target collector 14 collects unnecessary droplets DL.

The extreme ultraviolet light generation apparatus 100 includes a communication portion 19 providing communication between the internal space of the chamber 10 and the internal space of the exposure apparatus 200. A wall in which an aperture is formed is provided inside the communication portion 19. The wall is preferably arranged such that the aperture is located at the second focal point of the extreme ultraviolet light concentrating mirror 11.

Further, the extreme ultraviolet light generation apparatus 100 includes a pressure sensor 26. The pressure sensor 26 measures pressure at the internal space of the chamber 10. Further, the extreme ultraviolet light generation apparatus 100 includes a target sensor 27 attached to the chamber 10. The target sensor 27 has, for example, an imaging function, and detects the presence, trajectory, position, velocity, and the like of the droplet DL. The pressure sensor 26 and the target sensor 27 are electrically connected to the processor 20.

Further, a laser light concentrating optical system 13 is located in the chamber 10. The laser light concentrating optical system 13 includes a laser light concentrating mirror 13A and a high reflection mirror 13B. The laser light concentrating mirror 13A reflects and concentrates the pulse laser light 301 having passed through the window 12. The high reflection mirror 13B reflects the light concentrated by the laser light concentrating mirror 13A. Positions of the laser light concentrating mirror 13A and the high reflection mirror 13B are adjusted by the laser light manipulator 13C so that the laser light concentrating position in the chamber 10 coincides with a position specified by the processor 20.

A gas supply unit 63 which supplies an etching gas to an internal space of the chamber 10 is arranged at the chamber 10. The gas supply unit 63 is connected to an etching gas supply tank 64 through a pipe. When the target substance is tin, the etching gas is, for example, a balance gas having a hydrogen gas concentration of about 38. The balance gas may include a nitrogen (N₂) gas or an argon (Ar) gas.

The gas supply unit 63 is adjusted so that the etching gas supplied into the chamber 10 flows in the vicinity of the reflection surface of the extreme ultraviolet light concentrating mirror 11. When the target substance forming the droplet DL is turned into plasma in the plasma generation region AR, tin fine particles and tin ions are generated, and when tin fine particles and tin ions react with hydrogen, a stannane (SnH₄) gas at room temperature is generated. Here, a flow amount adjuster (not shown) is provided at a pipe between the gas supply unit 63 and the etching gas supply tank 64.

Further, a pair of exhaust portions 61 are arranged at the chamber 10. The exhaust portions 61 are configured to exhaust a residual gas in the chamber 10. Exhaust ports of the exhaust portions 61 are formed, for example, in a wall of the chamber 10 facing each other. The residual gas includes fine particles and charged particles generated by turning of target the substance plasma, products generated through the reaction of the fine particles and the charged particles with the etching gas, and an unreacted etching gas. Some of the charged particles are neutralized in the chamber 10, and the residual gas contains the neutralized charged particles as well. Further, the exhaust portions 61 are connected to an exhaust device 62, and the residual gas exhausted from the exhaust portions 61 are subjected to a predetermined exhaust treatment at the exhaust device 62. Here, at least one of the exhaust portions 61 may be provided with a trap mechanism such as a heater for trapping fine particles.

The travel direction of the pulse laser light 301 output from the laser device 30 is adjusted by a laser light delivery optical system 50. The laser light delivery optical system 50 includes a plurality of mirrors 51A, 51B for adjusting the travel direction of the pulse laser light 301, and a position of at least one of the mirrors 51A, 51B is adjusted by an actuator (not shown).

The laser device 30 includes a master oscillator being a light source to perform burst operation. The master oscillator emits the pulse laser light 301 in a pulse form in a burst-on duration. The master oscillator is, for example, a laser device configured to emit the laser light by exciting, through electric discharge, a gas as mixture of a carbon dioxide gas with helium, nitrogen, or the like. Alternatively, the master oscillator may be a quantum cascade laser device. The master oscillator emits the pulse laser light 301 in a pulse form by a Q switch system. The master oscillator may include an optical switch, a polarizer, and the like. In the burst operation, the continuous pulse laser light is emitted at a predetermined repetition frequency in the burst-on duration and the emission of the pulse laser light 301 is stopped in a burst-off duration.

The processor 20 includes a computer having a CPU and the like. The processor 20 is configured to control the entire extreme ultraviolet light generation apparatus 100, and also controls the laser device 30 as will be described below. The processor 20 receives a signal related to the pressure in the internal space of the chamber 10, which is measured by the pressure sensor 26, a signal related to image data of the droplet DL captured by the target sensor 27, a burst signal from the exposure apparatus 200, and the like. The processor 20 is configured to process the image data and the like, and to control, for example, timing at which the droplet DL is output, an output direction of the droplet DL, and the like. Such various kinds of control described above are merely examples, and other control is added as described later.

### 4. Description of Target Supply Device of Comparative Example

### 4.1 Configuration

Next, the configuration of the target supply device 40 will be described in more detail.

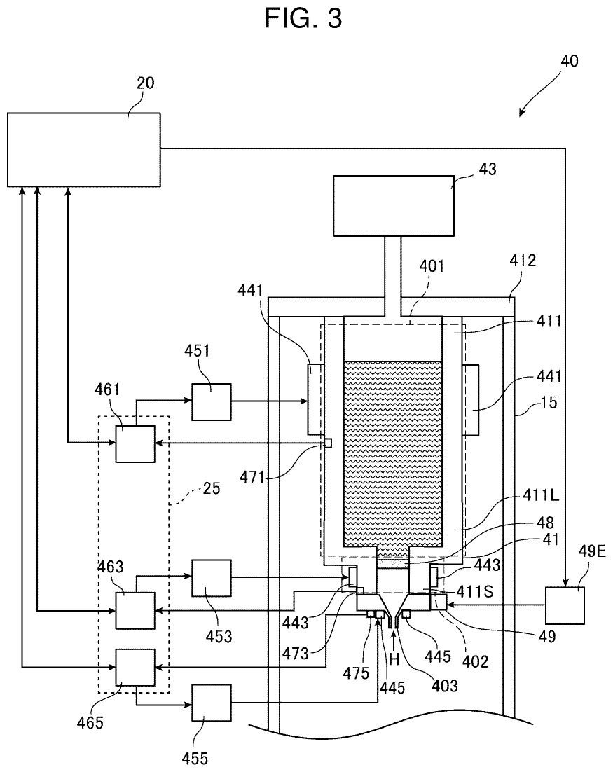

FIG. 3 is a schematic view showing a schematic configuration of the target supply device 40 of the comparative example. As shown in FIG. 3, the tank 41 of the target supply device 40 mainly includes a housing 411 and a lid 412. The housing 411 has a shape in which a large-diameter portion 411L and a small-diameter portion 411S having a smaller diameter than the large-diameter portion 411L are connected. The small-diameter portion 411S is connected to a lower end of the large-diameter portion 411L. An opening at an upper portion of the large-diameter portion 411L is blocked by the lid 412. An opening is formed in the lid 412, and a pipe connected to the pressure regulator 43 is inserted into the opening. An opening at a lower portion of the small-diameter portion 411S is blocked by the nozzle 403. A nozzle hole H is formed in the nozzle 403. In the tank 41 of the comparative example, the lid 412 is exposed to the outside of the chamber 10, and the housing 411 and the nozzle 403 are arranged in the space of the chamber 10. The housing 411 and the lid 412 are formed of, for example, molybdenum or tungsten.

The tank 41 is divided into a tank main body portion 401 and an intermediate portion 402 indicated by broken lines in FIG. 3. The tank main body portion 401 is located on an upper side of the tank 41, and the intermediate portion 402 is connected to the tank main body portion 401 and is located on a lower side of the tank 41. The tank main body portion 401 includes the large-diameter portion 411L of the housing 411. The intermediate portion 402 includes the small-diameter portion 411S of the housing 411. The capacity of the intermediate portion 402 is smaller than the capacity of the tank main body portion 401. A filter 48 is arranged in the intermediate portion 402 at a boundary on the tank main body portion 401 side. The filter 48 filters the molten target substance. The nozzle 403 outputs the target substance having passed through the filter 48 from the nozzle hole H as described above.

For example, the filter 48 is made of a porous material to collect metal oxides. The filter 48 is provided with a large number of through pores each having a diameter of about 3 μm to 10 μm, for example. The filter 48 is preferably formed of a material having low reactivity with the target substance. The difference between the linear thermal expansion coefficient of the material forming the filter 48 and the linear thermal expansion coefficient of the material forming the housing 411 is preferably smaller than 20% of the linear thermal expansion coefficient of the material forming the housing 411.

The nozzle 403 is preferably made of a material having a contact angle of 90° or more between a tip portion thereof and the target substance. When the target substance is tin, examples of the material forming the tip portion of the nozzle 403 include silicon carbide, silicon oxide, aluminum oxide, molybdenum, and tungsten. The nozzle 403 has, for example, a cylindrical shape, and the nozzle hole H is provided at the tip portion thereof. The inner diameter of the nozzle hole H is, for example, 3 μm.

A main heater 441 is arranged at the tank main body portion 401. A main heater temperature sensor 471 is arranged in the vicinity of a portion of the tank main body portion 401 where the main heater 441 is arranged.

The main heater 441 is connected to a main heater power source 451 and performs heating with the current applied from the main heater power source 451.

The main heater power source 451 is connected to a main heater temperature control processor 461, and the current to be applied to the main heater 441 is controlled by a signal from the main heater temperature control processor 461. The main heater temperature control processor 461 is connected to the processor 20 and the main heater temperature sensor 471, and controls the current to be applied from the main heater power source 451 to the main heater 441 based on signals from the processor 20 and the main heater temperature sensor 471.

An intermediate portion heater 443 is arranged at the intermediate portion 402. An intermediate portion temperature sensor 473 is arranged at the intermediate portion 402 in the vicinity of a portion where the intermediate portion heater 443 is arranged.

The intermediate portion heater 443 is connected to the intermediate portion heater power source 453 and performs heating with the current applied from the intermediate portion heater power source 453.

The intermediate portion heater power source 453 is connected to the intermediate portion heater temperature control processor 463, and the current to be applied to the intermediate portion heater 443 is controlled by a signal from the intermediate portion heater temperature control processor 463. The intermediate portion heater temperature control processor 463 is connected to the processor 20 and the intermediate portion temperature sensor and 473, controls the current to be applied from the intermediate portion heater power source 453 to the intermediate portion heater 443 based on signals from the processor 20 and the intermediate portion temperature sensor 473.

A sub-heater 445 is arranged at the nozzle 403. A sub-heater temperature sensor 475 is arranged in the vicinity of a portion where the sub-heater 445 is arranged. In the comparative example, the sub-heater temperature sensor 475 is arranged directly on the nozzle 403.

The sub-heater 445 is connected to the sub-heater power source 455 and performs heating with the current applied from the sub-heater power source 455.

The sub-heater power source 455 is connected to the sub-heater temperature control processor 465, and the current to be applied to the sub-heater 445 is controlled by a signal from the sub-heater temperature control processor 465. The sub-heater temperature control processor 465 is connected to the processor 20 and the sub-heater temperature sensor 475, and controls the current to be applied from the sub-heater power source 455 to the sub-heater 445 based on signals from the processor 20 and the sub-heater temperature sensor 475.

The main heater temperature control processor 461, the intermediate portion heater temperature control processor 463, and the sub-heater temperature control processor 465 configure a temperature control processor 25.

### 4.2 Operation

Operation when the target supply device 40 stops output of the target substance will be described.

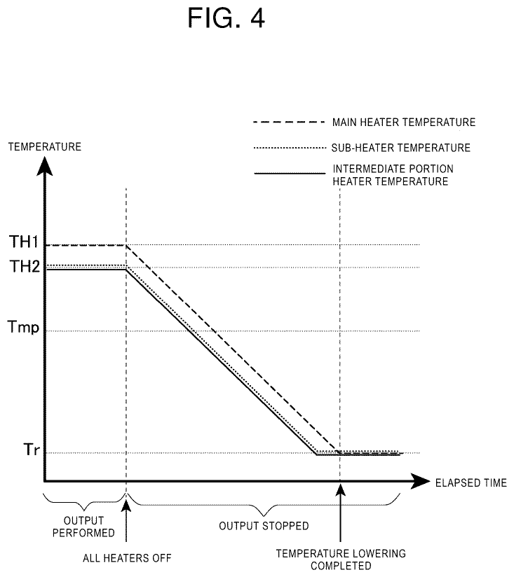

FIG. 4 is a graph showing a state of the temperature of each heater of the target supply device 40 of the comparative example. The temperature control processor 25 performs control so that the tank main body portion 401, the intermediate portion 402, and the nozzle 403 are maintained at a temperature higher than a melting point Tmp of the target substance when the droplet is output. Specifically, the tank main body portion 401 is maintained at a temperature TH1 higher than the melting point Tmp of the target substance, and the intermediate portion 402 and the nozzle 403 are maintained at a temperature TH2 higher than the melting point Imp of the target substance. The tank main body portion 401 having a large capacity is preferably maintained at a higher temperature than the intermediate portion 402 and the nozzle 403 in order to suppress melting failure of the target substance in the tank main body portion 401.

The processor 20 controls the pressure regulator 43 to lower the pressure in the tank 41, and the pressure regulator 43 lowers the pressure in the tank 41. Then, output of the droplet is stopped. The temperature control processor 25 controls the current applied to the main heater 441, the intermediate portion heater 443, and the sub-heater 445 to be zero. Then, the tank main body portion 401, the intermediate portion 402, and the nozzle 403 are cooled by heat radiation and gradually approach an ambient temperature Tr.

### 5. Problem

When the temperature of the target substance reaches the melting point or lower, ideally, the molten target substance uniformly solidifies and shrinks inside the intermediate portion 402 and the nozzle 403. Further, it is desired that a gap is uniformly formed around the solidified target substance. However, in practice, solidification shrinkage of the target substance does not occur uniformly.

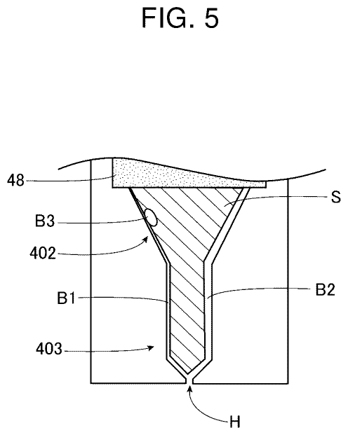

FIG. 5 is a schematic view showing a state of solidification shrinkage of the target substance around the intermediate portion 402 and the nozzle 403. A nonuniform gap is formed around the target substance S subjected to solidification shrinkage, and as shown in FIG. 5, it is considered that a narrow gap B1, wide gaps B2, B3, and the like occur, for example. Then, when purging is performed with an inert gas such as argon, a narrow part may hinder the purging, which may cause oxygen to remain. If oxygen remains in the intermediate portion 402 and the nozzle 403, the oxygen becomes a cause of the target substance to be oxidized when the target substance is remelted, and the oxidized target substance may inhibit output of the droplet and may adversely affect formation of the droplet.

Therefore, the following embodiments each exemplify a target supply device in which, when the target substance is cooled and solidified, gaps are aggregated and unnecessary oxidation of the target substance can be suppressed.

### 6. First Embodiment

### 6.1 Operation of Extreme Ultraviolet Light Generation Apparatus of First Embodiment

Next, operation of the target supply device according to a first embodiment will be described. Any component same as that described above is denoted by an identical reference sign, and duplicate description thereof is omitted unless specific description is needed. The configuration of the extreme ultraviolet light generation apparatus of the present embodiment is similar to the configuration of the extreme ultraviolet light generation apparatus of the comparative example, and therefore description thereof is omitted.

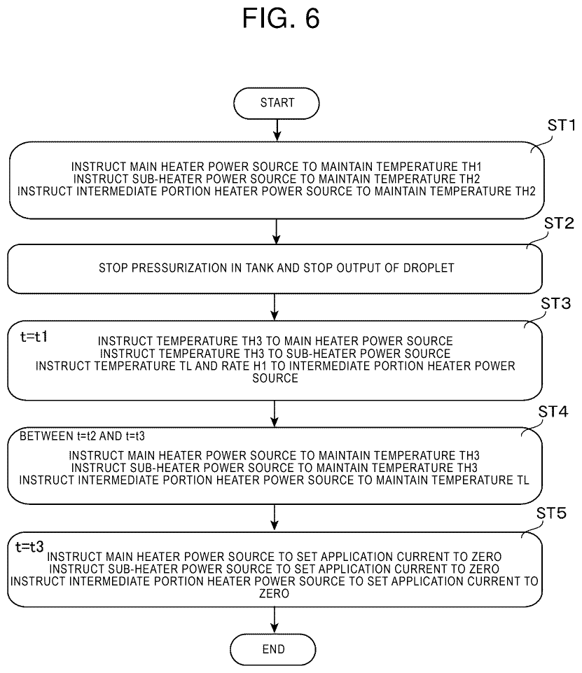

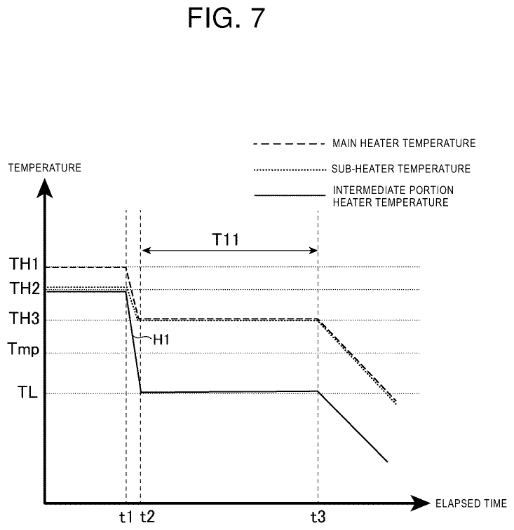

When the pressure at the internal space of the chamber 10 becomes a predetermined pressure in the same manner as operation of the extreme ultraviolet light generation apparatus 100 of the comparative example, output of the target substance is stopped. FIG. 6 is a flowchart showing operation of a control unit in the present embodiment, and FIG. 7 is a schematic view showing the state of the temperature of each heater of the target supply device 40 of the present embodiment.

### <Step ST1>

As shown in FIGS. 6 and 7, during droplet output, the temperature control processor 25 controls the temperature of the main heater 441 provided at the tank main body portion 401, the sub-heater 445 provided at the nozzle 403, and the intermediate portion heater 443 provided at the intermediate portion 402 to be maintained until an elapsed time t1. Specifically, the main heater temperature control processor 461 outputs a signal and instructs the main heater power source 451 to maintain the temperature of the main heater 441 at TH1, which is a temperature higher than the melting point Imp of the target substance. As a result, the current is applied from the main heater power source 451 to the main heater 441 so that the temperature of the main heater 441 becomes TH1. In the following, the description of “a processor instructing a temperature” includes causing a corresponding heater power source to apply the current to the corresponding heater so that the temperature of the heater becomes the instructed temperature. Similarly, the sub-heater temperature control processor 465 outputs a signal and instructs the sub-heater power source 455 to maintain the temperature of the sub-heater 445 at TH2, which is a temperature higher than the melting point Tmp of the target substance, and the intermediate portion heater temperature control processor 463 outputs a signal and instructs the intermediate portion heater power source 453 to maintain the temperature of the intermediate portion heater 443 at TH2.

When the target substance is tin, for example, TH1 is preferably 290° C. or higher and TH2 is preferably 260° C. or higher and 290° C. or lower.

### <Step ST2>

Before the elapsed time t1, the processor 20 stops pressurization in the tank to stop output of the target substance, that is, output of the droplet.

### <Step ST3>

At the elapsed time t1, the main heater temperature control processor 461 outputs a signal and instructs the main heater power source 451 to maintain the temperature of the main heater 441 at TH3. Further, the sub-heater temperature control processor 465 outputs a signal and instructs the sub-heater 445 to maintain the temperature at TH3. Further, the intermediate portion heater temperature control processor 463 outputs a signal and instructs the intermediate portion heater power source 453 to maintain the temperature of the intermediate portion heater 443 at TL.

Here, TH3 is preferably a temperature higher than the melting point Tmp of the target substance and lower than TH1 of the main heater 441 and TH2 of the sub-heater 445 at the time of droplet output. When the target substance is tin, TH3 is preferably a temperature included in a first temperature range of, for example, 232° C. or higher and 290° C. or lower. In the present embodiment, the temperature of the main heater 441 and the temperature of the sub-heater 445 are set to be the same temperature, but the present disclosure is not limited thereto. TL is a temperature lower than the melting point Imp of the target substance. TL is preferably a temperature included in a second temperature range of, for example, 150° C. or higher and 200° C. or lower. TL is preferably a temperature lower than TH3 by 100° C. or more and 140° C. or less.

That is, in the temperature lowering control, the temperature control processor 25 sets the temperature of the intermediate portion heater 443 to a temperature lower than the melting point Tmp of the target substance while setting the temperature of the main heater 441 and the temperature of the sub-heater 445 to a temperature higher than the melting point Imp of the target substance.

In a period between the elapsed time t1 and an elapsed time t2, the intermediate portion heater temperature control processor 463 may instruct the intermediate portion heater power source 453 to output a signal including a temperature lowering rate H1 to adjust the temperature lowering rate. The temperature lowering rate H1 is a rate causing the temperature of the intermediate portion heater 443 to become TL at the elapsed time t2. That is, the intermediate portion heater temperature control processor 463 controls the intermediate portion heater power source 453 to apply the current from the intermediate portion heater power source 453 to the intermediate portion heater 443 so that the temperature lowering rate of the intermediate portion heater 443 becomes H1. Further, for example, when the temperature of the intermediate portion heater 443 becomes lower than the melting point Tmp of the target substance, the temperature lowering rate may be increased. Accordingly, the time required for shutting down the target supply device 40 can be shortened.

### <Step ST4>

In a first predetermined period T11 between the elapsed time t2 and an elapsed time t3, the main heater temperature control processor 461 controls the main heater power source 451 to maintain the temperature of the main heater 441 at TH3. Further, the sub-heater temperature control processor 465 controls the sub-heater power source 455 to maintain the temperature of the sub-heater 445 at TH3.

Further, in the first predetermined period T11 between the elapsed time t2 and the elapsed time t3, the intermediate portion heater temperature control processor 463 controls the intermediate portion heater power source 453 to maintain the temperature of the intermediate portion heater 443 at TL.

Here, the first predetermined period T11 between the elapsed time t2 and the elapsed time t3 is preferably 10 minutes or longer. The first predetermined period T11 between the elapsed time t2 and the elapsed time t3 is more preferably 60 minutes or longer.

### <Step ST5>

At the elapsed time t3, the temperature control processor 25 controls the main heater power source 451, the sub-heater power source 455, and the intermediate portion heater power source 453 so that the current applied to each of the main heater 441, the sub-heater 445, and the intermediate portion heater 443 becomes zero.

### 6.2 Effect

In the present embodiment, after the processor 20 stops output of the target substance, the temperature control processor 25 performs temperature lowering control of the main heater 441, the sub-heater 445, and the intermediate portion heater 443. In the temperature lowering control, the temperature control processor 25 maintains the temperature of the intermediate portion heater 443 lower than the melting point Imp of the target substance while maintaining the temperature of the main heater 441 and the temperature of the sub-heater 445 at a temperature higher than the melting point Tmp of the target substance. Then, in accordance with solidification shrinkage of the target substance in the intermediate portion 402, the target substance melted in the tank main body portion 401 and the nozzle 403 is drawn into the intermediate portion 402.

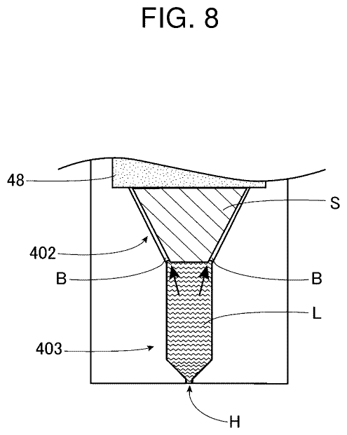

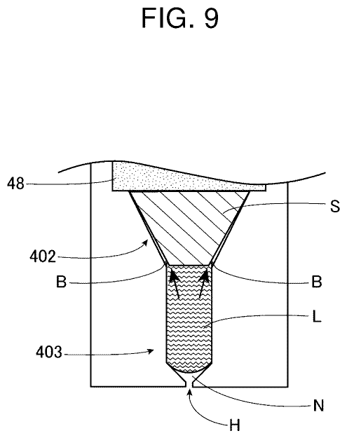

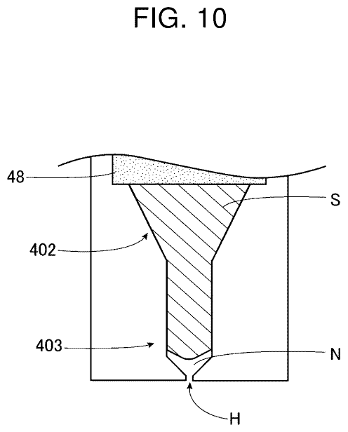

FIGS. 8, 9, and 10 are schematic views showing how the target substance melted in the tank main body portion 401 and the nozzle 403 is drawn into the intermediate portion 402 in accordance with solidification shrinkage of the target substance in the intermediate portion 402 during the first predetermined period T11. FIG. 8 shows a state when the temperature of the intermediate portion heater 443 starts to be lower than the melting point Tmp of the target substance. At this time, the target substance starts to solidify and shrink, and it is considered that the gap B is formed around the solidified target substance S. During the first predetermined period T11, since the main heater 441 and the sub-heater 445 are maintained at a temperature higher than the melting point Imp of the target substance, a target substance L at the inside of the tank main body portion 401 and the inside of the nozzle 403 is molten. Then, the molten target substance L is drawn in a direction of the arrows shown in FIG. 9, and when the target substance is solidified, a gap is less likely to be formed in the intermediate portion 402. Finally, when the target substance L in the nozzle 403 is solidified and cooled, a single gap N is likely to be formed directly above the nozzle hole H as shown in FIG. 10. The formation of the single gap N can enhance the effect of reducing residual oxygen when purging with an inert gas is performed, and can further reduce troubles associated with oxidation of the target substance.

Further, in the present embodiment, it is preferable that the intermediate portion heater temperature control processor 463 be capable of controlling the intermediate portion heater power source 453 to adjust the temperature lowering rate of the intermediate portion heater 443. Since the drawing velocity of the molten target substance in the nozzle 403 can be reduced, it may be less likely that the target substance remains at the tip of the nozzle 403.

Here, the temperature lowering rate of the intermediate portion heater 443 may be changed in accordance with the elapsed time. For example, the temperature lowering rate may be decreased in a period between the elapsed time t1 and the elapsed time t2 in the present embodiment. Specifically, for example, when the temperature lowering rate before time t between the elapsed time t1 and the elapsed time t2 is H2 and the temperature lowering rate after the time t is H3, it is preferable that H2>H3 is satisfied, but H2≤H3 may be adopted. Further, the temperature lowering rate of the sub-heater 445 may also be adjustable by the sub-heater temperature control processor 465 controlling the sub-heater power source 455. When the temperature lowering rate of the intermediate portion heater 443 is H1 and the temperature lowering rate of the sub-heater 445 is H4, it is preferable that H1>H4 is satisfied, but H1≤H4 may be adopted.

In the present embodiment, the temperature of the main heater 441 and the temperature of the sub-heater 445 are set to TH3 which is a temperature lower than TH1 and TH2 so that the time required for the temperature lowering control can be shortened.

In the present embodiment, the temperature of the main heater 441 and the temperature of the sub-heater 445 are lowered to the same TH3 which is a temperature lower than TH1 and TH2 but need not be the same temperature.

In the present embodiment, the temperature of the main heater 441 and the temperature of the sub-heater 445 are set to TH3 which is a temperature lower than TH1 and TH2 during the first predetermined period T11, but may be maintained at the temperature when the target substance is output.

Further, in the present embodiment, temperature lowering of the main heater 441 and the sub-heater 445 is started at the elapsed time t3. However, temperature lowering may be started from any heater.

During the first predetermined period T11, the sub-heater temperature control processor 465 may control the sub-heater power source 455 to maintain the temperature of the sub-heater 445 in the first temperature range higher than the melting point Imp of the target substance, and the main heater temperature control processor 461 may control the main heater power source 451 to maintain the temperature of the main heater 441 in the second temperature range lower than the melting point Tmp of the target substance.

When the target substance is tin, TH3 is preferably a temperature included in the first temperature range of 232° C. or higher and 290° C. or lower, but TH3 is only required to be a temperature equal to or higher than the melting point Tmp of the target substance. Further, when the target substance is tin, TL is preferably a temperature included in the second temperature range of 150° C. or higher and 200° C. or lower, but TL is only required to be a temperature equal to or lower than the melting point Tmp of the target substance.

In the present embodiment, in the first predetermined period T11 between the elapsed time t2 and the elapsed time t3, the intermediate portion heater temperature control processor 463 controls the intermediate portion heater power source 453 to maintain the temperature of the intermediate portion heater 443 at TL, but the present disclosure is not limited thereto. For example, at the elapsed time t2, the temperature control processor 25 may control the current applied to the intermediate portion heater 443 to be zero.

Further, in the present embodiment, an example in which the temperature control processor 25 controls the current applied to the main heater 441, the sub-heater 445, and the intermediate portion heater 443 to be zero at the elapsed time t3 has been described, but the temperature of each heater may be maintained at, for example, 100° C. or lower.

### 7. Second Embodiment

### 7.1 Configuration of Extreme Ultraviolet Light Generation Apparatus of Second Embodiment

Configuration of the target supply device according to a second embodiment will be described. Any component same as that described above is denoted by an identical reference sign, and duplicate description thereof is omitted unless specific description is needed. Since the configuration of the extreme ultraviolet light generation apparatus of the present embodiment is similar to the configuration of the extreme ultraviolet light generation apparatus of the comparative example except for the configuration of the target supply device, description of the configuration of the extreme ultraviolet light generation apparatus including the target supply device of the present embodiment will be omitted.

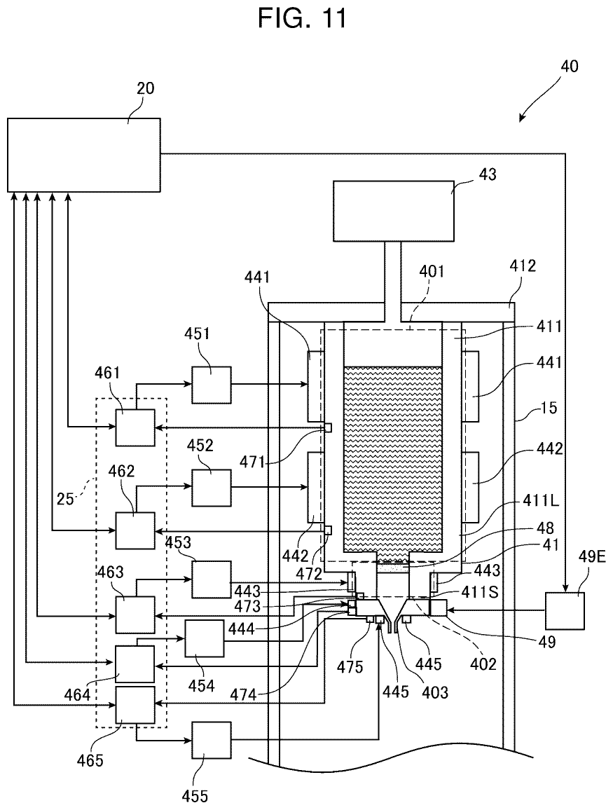

FIG. 11 is a schematic view showing a schematic configuration of the target supply device 40 of the present embodiment. The target supply device 40 of the present embodiment is different from that of the first embodiment in that it includes a second main heater 442 located closer to the intermediate portion 402 than the main heater 441 of the first embodiment, and includes a second sub-heater 444 located closer to the intermediate portion 402 than the sub-heater 445 of the first embodiment. Further, the target supply device 40 of the present embodiment is different from that of the first embodiment in that it includes a second main heater power source 452 that applies the current to the second main heater 442, a second main heater temperature control processor 462 that controls the second main heater 442, a second sub-heater power source 454 that applies the current to the second sub-heater 444, and a second sub-heater temperature control processor 464 that controls the second sub-heater 444.

In the present embodiment, the first main heater temperature control processor 461, the second main heater temperature control processor 462, the intermediate portion heater temperature control processor 463, the first sub-heater temperature control processor 465, and the second sub-heater temperature control processor 464 configure the temperature control processor 25.

In the present embodiment, what has been referred to as the main heater 441 in the first embodiment is read as a first main heater 441, and what has been referred to as the sub-heater 445 in the first embodiment is read as a first sub-heater 445. Similarly, what has been referred to as the main heater temperature control processor 461, the main heater power source 451, and the main heater temperature sensor 471 in the first embodiment are read as the first main heater temperature control processor 461, a first main heater power source 451, and a first main heater temperature sensor 471, respectively. Similarly, what has been referred to as the sub-heater temperature control processor 465, the sub-heater power source 455, and the sub-heater temperature sensor 475 in the first embodiment are read as the first sub-heater temperature control processor 465, a first sub-heater power source 455, and a first sub-heater temperature sensor 475, respectively.

The second main heater 442 is arranged at the tank main body portion 401. A second main temperature sensor 472 is arranged in the vicinity of a portion of the tank main body portion 401 where the second main heater 442 is arranged.

The second main heater 442 is connected to the second main heater power source 452 and performs heating with the current applied from the second main heater power source 452.

The second main heater power source 452 is connected to the second main heater temperature control processor 462, and the current to be applied to the second main heater 442 is controlled by a signal from the second main heater temperature control processor 462. The second main heater temperature control processor 462 is connected to the second main temperature sensor 472, and controls the current to be applied from the second main heater power source 452 to the second main heater 442 based on a signal from the second main temperature sensor 472.

The second sub-heater 444 is arranged at the nozzle 403. A second sub-temperature sensor 474 is arranged in the vicinity of a portion where the second sub-heater 444 is arranged. In the present embodiment, the second sub-temperature sensor 474 is arranged directly on the nozzle 403.

The second sub-heater 444 is connected to the second sub-heater power source 454 and performs heating with the current applied from the second sub-heater power source 454.

The second sub-heater power source 454 is connected to the second sub-heater temperature control processor 464, and the current to be applied to the second sub-heater 444 is controlled by a signal from the second sub-heater temperature control processor 464. The second sub-heater temperature control processor 464 is connected to the second sub-temperature sensor 474, and controls the current to be applied from the second sub-heater power source 454 to the second sub-heater 444 based on a signal from the second sub-temperature sensor 474.

### 7.2 Operation of Extreme Ultraviolet Light Generation Apparatus of Second Embodiment

Next, operation of the target supply device according to the second embodiment will be described.

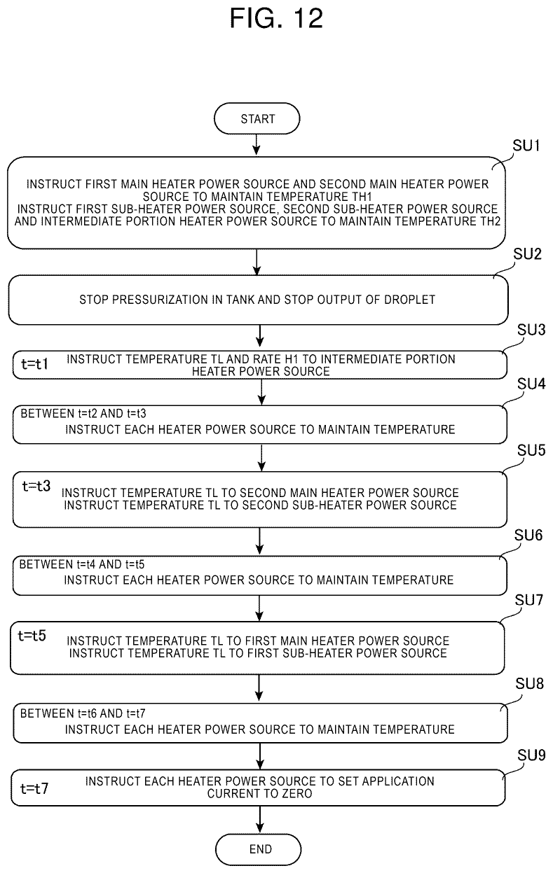

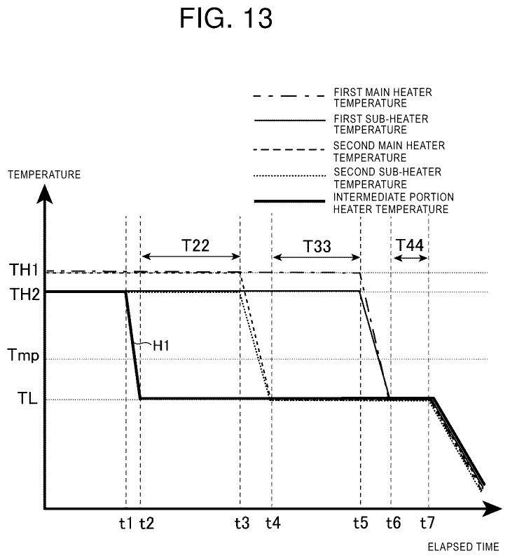

When the pressure at the internal space of the chamber 10 becomes a predetermined pressure in the same manner as operation of the extreme ultraviolet light generation apparatus 100 of the comparative example, output of the target substance is stopped. FIG. 12 is a flowchart showing operation of the control unit in the present embodiment, and FIG. 13 is a schematic view showing the state of the temperature of the target supply device 40 of the present embodiment.

### <Step SU1>

As shown in FIGS. 12 and 13, the temperature control processor 25 controls the temperature of each of the first main heater 441 and the second main heater 442 provided at the tank main body portion 401, the first sub-heater 445 and the second sub-heater 444 provided at the nozzle 403, and the intermediate portion heater 443 provided at the intermediate portion 402 to be maintained until the elapsed time t1. Specifically, the temperature control processor 25 outputs a signal and instructs the first main heater power source 451 and the second main heater power source 452 to maintain the temperature of the first main heater 441 and the second main heater 442 at TH1, respectively. Further, the temperature control processor 25 outputs a signal and instructs the first sub-heater power source 455 and the second sub-heater 454 power source to maintain the temperature of the first sub-heater 445 and the second sub-heater 444 at TH2, respectively. Similarly, the temperature control processor 25 outputs a signal and instructs the intermediate portion heater power source 453 to maintain the temperature of the intermediate portion heater 443 at TH2.

The intermediate portion heater temperature control processor 463 controls the intermediate portion heater power source 453 to apply the current from the intermediate portion heater power source 453 to the intermediate portion heater 443 so that the temperature of the intermediate portion heater 443 becomes TH2.

TH1 and TH2 are temperatures higher than the melting point Tmp of the target substance, and when the target substance is tin, TH1 is 280° C. or higher and 290° C. or lower and TH2 is 232° C. or higher and 280° C. or lower, for example. TH1 and TH2 are only required to be included in the first temperature range of 232° C. or higher and 290° C. or lower.

### <Step SU2>

Before the elapsed time t1, the processor 20 stops pressurization in the tank to stop output of the target substance, that is, output of the droplet.

### <Step SU3>

At the elapsed time t1, the second main heater temperature control processor 462 maintains the temperature of the second main heater 442 at TH1, and the second sub-heater temperature control processor 464 maintains the temperature of the second sub-heater 444 at TH2. The first main heater temperature control processor 461 maintains the temperature of the first main heater 441 at TH1, and the first sub-heater temperature control processor 465 maintains the temperature of the first sub-heater 445 at TH2. Specifically, the first main heater temperature control processor 461 outputs a signal and instructs the first main heater power source 451 to maintain the temperature of the first main heater 441 at TH1. The second main heater temperature control processor 462 outputs a signal and instructs the second main heater power source 452 to maintain the temperature of the second main heater 442 at TH1.

The intermediate portion heater temperature control processor 463 sets the temperature of the intermediate portion heater 443 to TL. TL is a temperature lower than the melting point Tmp of the target substance. TL is preferably a temperature included in a second temperature range of, for example, 150° C. or higher and 200° C. or lower. TL is preferably a temperature lower than TH1 by 100° C. or more and 140° C. or less.

Further, in a period between the elapsed time t1 and the elapsed time t2, the intermediate portion heater temperature control processor 463 outputs a signal including the temperature lowering rate H1 and provides instruction to the intermediate portion heater power source 453. The temperature lowering rate H1 is a rate causing the temperature of the intermediate portion heater 443 to become TL at the elapsed time t2. That is, the intermediate portion heater temperature control processor 463 controls the intermediate portion heater power source 453 to apply the current from the intermediate portion heater power source 453 to the intermediate portion heater 443 so that the temperature lowering rate of the intermediate portion heater 443 becomes H1.

### <Step SU4>

In a second predetermined period T22 between the elapsed time t2 and the elapsed time t3, the first main heater temperature control processor 461 controls the first main heater power source 451 to maintain the temperature of the first main heater 441 at TH1. The second main heater temperature control processor 462 controls the second main heater power source 452 to maintain the temperature of the second main heater 442 at TH1. Further, the first sub-heater temperature control processor 465 controls the first sub-heater power source 455 to maintain the temperature of the at first sub-heater 445 TH2. The second sub-heater temperature control processor 464 controls the second sub-heater power source 454 to maintain the temperature of the second sub-heater 444 at TH2.

Further, in the second predetermined period T22 between the elapsed time t2 and the elapsed time t3, the intermediate portion heater temperature control processor 463 controls the intermediate portion heater power source 453 to maintain the temperature of the intermediate portion heater 443 at TL.

Here, the second predetermined period T22 between the elapsed time t2 and the elapsed time t3 is preferably 10 minutes or longer. The second predetermined period T22 between the elapsed time t2 and the elapsed time t3 is more preferably 60 minutes or longer.

### <Step SU5>

At the elapsed time t3, the second main heater temperature control processor 462 lowers the temperature of the second main heater 442 to TL. The second sub-heater temperature control processor 464 lowers the temperature of the second sub-heater 444 to TL. The first main heater temperature control processor 461 maintains the temperature of the first main heater 441 at TH1, and the first sub-heater temperature control processor 465 maintains the temperature of the first sub-heater 445 at TH2. Specifically, the second main heater temperature control processor 462 outputs a signal and instructs the second main heater power source 452 to maintain the temperature of the second main heater 442 at TL. The second sub-heater temperature control processor 464 outputs a signal and instructs the second sub-heater power source 454 to maintain the temperature of the second sub-heater 444 at TL. Further, the first main heater temperature control processor 461 outputs a signal and instructs the first main heater power source 451 to maintain the temperature of the first main heater 441 at TH1. The first sub-heater temperature control processor 465 outputs a signal and instructs the first sub-heater power source 455 to maintain the temperature of the first sub-heater 445 at TH2.

### <Step SU6>

In a third predetermined period T33 between an elapsed time t4 and an elapsed time t5, the first main heater temperature control processor 461 controls the first main heater power source 451 to maintain the temperature of the first main heater 441 at TH1. The second main heater temperature control processor 462 controls the second main heater power source 452 to maintain the temperature of the second main heater 442 at TL. Further, the first sub-heater temperature control processor 465 controls the first sub-heater power source 455 to maintain the temperature of the first sub-heater 445 at TH2. The second sub-heater temperature control processor 464 controls the second sub-heater power source 454 to maintain the temperature of the second sub-heater 444 at TL.

Further, in the third predetermined period T33 between the elapsed time t4 and the elapsed time t5, the intermediate portion heater temperature control processor 463 controls the intermediate portion heater power source 453 to maintain the temperature of the intermediate portion heater 443 at TL.

That is, in the temperature lowering control, the temperature control processor 25 sets the temperature of the intermediate portion heater 443 to a temperature lower than the melting point Tmp of the target substance while setting the temperature of the first main heater 441, the temperature of the first sub-heater 445, the temperature of the second main heater 442, and the temperature of the second sub-heater 444 to a temperature higher than the melting point Tmp of the target substance, and then sets the temperature of the second main heater 442 and the temperature of the second sub-heater 444 to a temperature lower than the melting point Tmp of the target substance while setting the temperature of the first main heater 441 and the temperature of the first sub-heater 445 to a temperature higher than the melting point Tmp of the target substance.

Here, the third predetermined period T33 between the elapsed time t4 and the elapsed time t5 is preferably 10 minutes or longer. The third predetermined period T33 between the elapsed time t4 and the elapsed time t5 is more preferably 60 minutes or longer.

### <Step SU7>

At the elapsed time t5, the first main heater temperature control processor 461 lowers the temperature of the first main heater 441 to TL. The first sub-heater temperature control processor 465 lowers the temperature of the first sub-heater 445 to TL. The second main heater temperature control processor 462 maintains the temperature of the second main heater 442 at TL, and the second sub-heater temperature control processor 464 maintains the temperature of the second sub-heater 444 at TL. Specifically, the first main heater temperature control processor 461 outputs a signal and instructs the first main heater power source 451 to maintain the temperature of the first main heater 441 at TL. The first sub-heater temperature control processor 465 outputs a signal and instructs the first sub-heater power source 455 to maintain the temperature of the first sub-heater 445 at TL. Further, the second main heater temperature control processor 462 outputs a signal and instructs the second main heater power source 452 to maintain the temperature of the second main heater 442 at TL. The second sub-heater temperature control processor 464 outputs a signal and instructs the second sub-heater power source 454 to maintain the temperature of the second sub-heater 444 at TL.

### <Step SU8>

In a fourth predetermined period T44 between an elapsed time t6 and an elapsed time t7, the first main heater temperature control processor 461 controls the first main heater power source 451 to maintain the temperature of the first main heater 441 at TL. The second main heater temperature control processor 462 controls the second main heater power source 452 to maintain the temperature of the second main heater 442 at TL. Further, the first sub-heater temperature control processor 465 controls the first sub-heater power source 455 to maintain the temperature of the first sub-heater 445 at TL. The second sub-heater temperature control processor 464 controls the second sub-heater power source 454 to maintain the temperature of the second sub-heater 444 at TL.

Further, in the fourth predetermined period T44 between the elapsed time t6 and the elapsed time t7, the intermediate portion heater temperature control processor 463 controls the intermediate portion heater power source 453 to maintain the temperature of the intermediate portion heater 443 at TL.

### <Step SU9>

At the elapsed time t7, the temperature control processor 25 controls the first main heater power source 451, the second main heater power source 452, the first sub-heater power source 455, the second sub-heater power source 454, and the intermediate portion heater power source 453 so that the current applied to each of the first main heater 441, the second main heater 442, the first sub-heater 445, the second sub-heater 444, and the intermediate portion heater 443 becomes zero.

### 7.3 Effect

In the present embodiment, since the target substance is cooled to a temperature equal to or lower than the melting point Imp of the target substance in order from the side close to the intermediate portion 402, the molten target substance can be more drawn to the intermediate portion 402 side. Therefore, when the target substance solidifies, a gap is less likely to be formed in the intermediate portion 402. Therefore, since remaining oxygen in the nozzle 403 and the intermediate portion 402 is less likely to remain in the solidified target substance during the temperature lowering control, oxidation of the target substance when the target substance is remelted can be suppressed, and output of the target substance from the nozzle hole H can be further suppressed from being hindered by the oxidized target substance.

In the present embodiment, an example in which both the second main heater 442 and the second sub-heater 444 are included in addition to the first main heater 441 and the first sub-heater 445 is shown, but the present disclosure is not limited thereto. Only one of the second main heater 442 and the second sub-heater 444 may be included. In a case that only the second main heater is included, in the temperature lowering control, the temperature control processor 25 may set the temperature of the intermediate portion heater 443 to a temperature lower than the melting point Tmp of the target substance while setting the temperature of the first main heater 441, the temperature of the second main heater 442, and the temperature of the first sub-heater 445 to a temperature higher than the melting point Tmp of the target substance, and then set the temperature of the second main heater 442 to a temperature lower than the melting point Imp of the target substance while setting the temperature of the first main heater 441 and the temperature of the first sub-heater 445 to a temperature higher than the melting point Tmp of the target substance. Further, in the temperature lowering control, the temperature control processor 25 may set the temperature of the intermediate portion heater 443 to a temperature lower than the melting point Tmp of the target substance while setting the temperature of the first main heater 441, the temperature of the first sub-heater 445, and the temperature of the second sub-heater 444 to a temperature higher than the melting point Tmp of the target substance, and then set the temperature of the second sub-heater 444 to a temperature lower than the melting point Imp of the target substance while setting the temperature of the first main heater 441 and the temperature of the first sub-heater 445 to a temperature higher than the melting point Tmp of the target substance.

In the present embodiment, in the third predetermined period T33 between the elapsed time t4 and the elapsed time t5, the second main heater temperature control processor 462 controls the second main heater power source 452 to maintain the temperature of the second main heater 442 at TL, and the second sub-heater temperature control processor 464 controls the second sub-heater power source 454 to maintain the temperature of the second sub-heater 444 at TL, but the present disclosure is not limited thereto. For example, control is performed by corresponding temperature control processors such that one of the temperature of the second main heater 442 and the temperature of the second sub-heater 444 is maintained at TL and the other is maintained at a temperature at the time of the elapsed time t3. By cooling from the side close to the intermediate portion, the molten target substance is easily drawn toward the intermediate portion side. Therefore, the single gap N is likely to be formed directly above the nozzle hole H. The formation of the single gap N can enhance the effect of reducing residual oxygen when purging with an inert gas is performed, and can further reduce troubles associated with oxidation of the target substance.

In the present embodiment, in the third predetermined period T33 between the elapsed time t4 and the elapsed time t5, the first main heater temperature control processor 461 may control the first main heater power source 451 to maintain the temperature of the first main heater 441 in the second temperature range lower than the melting point Tmp of the target substance.

Further, in the third predetermined period T33 between the elapsed time t4 and the elapsed time t5, the first sub-heater temperature control processor 465 may control the first sub-heater power source 455 to maintain the temperature of the first sub-heater 445 in the second temperature range lower than the melting point Tmp of the target substance.

In the present embodiment, when the target substance is tin, TH1 and TH2 are preferably included in the first temperature range of 232° C. or higher and 290° C. or lower, but TH1 and TH2 are only required to be a temperature equal to or higher than the melting point Tmp of the target substance. Further, when the target substance is tin, TL is preferably a temperature included in the second temperature range of 150° C. or higher and 200° C. or lower, but TL is only required to be a temperature equal to or lower than the melting point Tmp of the target substance.

In the present embodiment, the temperature of each heater is maintained at TL during the fourth predetermined period T44 between the elapsed time t6 and the elapsed time t7, but the present disclosure is not limited thereto. For example, at the elapsed time t6, the temperature control processor 25 may control the first main heater power source 451, the second main heater power source 452, the first sub-heater power source 455, the second sub-heater power source 454, and the intermediate portion heater power source 453 so that the current applied to each of the first main heater 441, the second main heater 442, the first sub-heater 445, the second sub-heater 444, and the intermediate portion heater 443 becomes zero.

In the present embodiment, the temperature of the intermediate portion heater 443 is maintained at TL in a period between the elapsed time t2 and the elapsed time t7, but the present disclosure is not limited thereto. For example, at any time after the elapsed time t2, the intermediate portion heater temperature control processor 463 may control the intermediate portion heater power source 453 so that the current applied to the intermediate portion heater 443 becomes zero.

Further, in the present embodiment, the temperature of the second sub-heater 444 and the temperature of the second main heater 442 are maintained at TL in a period between the elapsed time t4 and the elapsed time t5, but the present disclosure is not limited thereto. For example, at any time after the elapsed time t4, the temperature control processor 25 may control the second sub-heater power source 454 and the second main heater power source 452 so that the current applied to at least one of the second sub-heater 444 and the second main heater 442 becomes zero.

Further, in the present embodiment as well, the temperature lowering rate of the intermediate portion heater 443 may be changed in accordance with the elapsed time. For example, the temperature lowering rate may be decreased in a period between the elapsed time t1 and the elapsed time t2 in the present embodiment. Specifically, for example, when the temperature lowering rate before time t between the elapsed time t1 and the elapsed time t2 is H2 and the temperature lowering rate after the time t is H3, it is preferable that H2>H3 is satisfied, but H2<H3 may be adopted. Further, the temperature lowering rate of the first sub-heater 445 may also be adjustable by the first sub-heater temperature control processor 465 controlling the first sub-heater power source 455. When the temperature lowering rate of the intermediate portion heater 443 is H1 and the temperature lowering rate of the first sub-heater 445 is H4, it is preferable that H1>H4 is satisfied, but H1≤H4 may be adopted. Further, the temperature lowering rate of the second sub-heater 444 may also be adjustable by the second sub-heater temperature control processor 464 controlling the second sub-heater power source 454. When the temperature lowering rate of the intermediate portion heater 443 is H1 and the temperature lowering rate of the second sub-heater 444 is H5, it is preferable that H1>H5 is satisfied, but H1≤H5 may be adopted. Further, the temperature lowering rate of the first main heater 441 and the second main heater 442 may also be adjustable.

Here, the intermediate portion 402 is a portion connecting the tank main body portion 401 which contains the target substance and the nozzle 403 which outputs the target substance, and various forms are conceivable. Thus, the intermediate portion 402 is not limited to the shape described in the embodiments. For example, in a case in which the nozzle 403 is tapered from the intermediate portion 402 and cannot be clearly distinguished, it is interpreted that the position of the heater provided at the position farthest from the tank main body portion 401 corresponds to the nozzle 403, and the position of the heater provided at the position closest to the tank main body portion 401 corresponds to the intermediate portion 402.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined. The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A target supply device comprising:
a tank main body portion configured to contain a target substance;
an output portion configured to output the target substance;
an intermediate portion located between the tank main body portion and the output portion;
a first main heater configured to heat the tank main body portion;
a first sub-heater configured to heat the output portion;
an intermediate portion heater configured to heat the intermediate portion; and
a temperature control processor configured to perform temperature lowering control of the first main heater, the first sub-heater, and the intermediate portion heater after output of the target substance is stopped,
the temperature control processor setting, in the temperature lowering control, a temperature of the intermediate portion heater to a temperature lower than a melting point of the target substance while setting each of a temperature of the first main heater and a temperature of the first sub-heater to a temperature higher than the melting point of the target substance.

2. The target supply device according to claim 1,
wherein, during a first predetermined period in the temperature lowering control, the temperature control processor maintains the temperature of the intermediate portion heater in a second temperature range lower than the melting point of the target substance while maintaining the temperature of the first main heater and the temperature of the first sub-heater in a first temperature range higher than the melting point of the target substance.

3. The target supply device according to claim 2,
wherein the first predetermined period is 10 minutes or longer.

4. The target supply device according to claim 2,
wherein the target substance is tin, and
the first temperature range is a temperature range of 232° C. or higher and 290° C. or lower.

5. The target supply device according to claim 2,
wherein the target substance is tin, and
the second temperature range is a temperature range of 150° C. or higher and 200° C. or lower.

6. The target supply device according to claim 4,
wherein the second temperature range is a temperature range lower than the temperature of the first sub-heater by 100° C. or more and 140° C. or less.

7. The target supply device according to claim 2,
wherein the first temperature range is a temperature range lower than the temperature of the first main heater and the temperature of the first sub-heater when the target substance is output.

8. The target supply device according to claim 1,
wherein the temperature control processor adjusts a temperature lowering rate of the intermediate portion heater.

9. The target supply device according to claim 1,
further comprising a second sub-heater located closer to the intermediate portion than the first sub-heater and configured to heat the output portion,
wherein, in the temperature lowering control, the temperature control processor sets the temperature of the intermediate portion heater to a temperature lower than the melting point of the target substance while setting each of the temperature of the first main heater, the temperature of the first sub-heater, and a temperature of the second sub-heater to a temperature higher than the melting point of the target substance, and then sets the temperature of the second sub-heater to a temperature lower than the melting point of the target substance while setting each of the temperature of the first main heater and the temperature of the first sub-heater to a temperature higher than the melting point of the target substance.

10. The target supply device according to claim 9,
wherein, in the temperature lowering control, the temperature control processor, during a second predetermined period, maintains the temperature of the intermediate portion heater in a second temperature range lower than the melting point of the target substance while maintaining the temperature of the first main heater, the temperature of the first sub-heater and the temperature of the second sub-heater in a first temperature range higher than the melting point of the target substance, and then, during a third predetermined period, maintains the temperature of the second sub-heater in the second temperature range while maintaining the temperature of the first main heater and the temperature of the first sub-heater in the first temperature range.

11. The target supply device according to claim 1, further comprising:
a second sub-heater located closer to the intermediate portion than the first sub-heater and configured to heat the output portion, and
a second main heater located closer to the intermediate portion than the first main heater and configured to heat the tank main body portion,
wherein, in the temperature lowering control, the temperature control processor sets the temperature of the intermediate portion heater to a temperature lower than the melting point of the target substance while setting each of the temperature of the first main heater, the temperature of the first sub-heater, a temperature of the second main heater, and a temperature of the second sub-heater to a temperature higher than the melting point of the target substance, and then sets each of the temperature of the second main heater and the temperature of the second sub-heater to a temperature lower than the melting point of the target substance while setting each of the temperature of the first main heater and the temperature of the first sub-heater to a temperature higher than the melting point of the target substance.

12. The target supply device according to claim 11,
wherein, in the temperature lowering control, the temperature control processor, during a second predetermined period, maintains the temperature of the intermediate portion heater in a second temperature range lower than the melting point of the target substance while maintaining the temperature of the first main heater, the temperature of the second main heater, the temperature of the first sub-heater, and the temperature of the second sub-heater in a first temperature range higher than the melting point of the target substance, and then, during a third predetermined period, maintains the temperature of the second main heater and the temperature of the second sub-heater in the second temperature range while maintaining the temperature of the first main heater and the temperature of the first sub-heater in the first temperature range.

13. The target supply device according to claim 1,
further comprising a second main heater located closer to the intermediate portion than the first main heater and configured to heat the tank main body portion,
wherein, in the temperature lowering control, the temperature control processor sets the temperature of the intermediate portion heater to a temperature lower than the melting point of the target substance while setting each of the temperature of the first main heater, a temperature of the second main heater, and the temperature of the first sub-heater to a temperature higher than the melting point of the target substance, and then sets the temperature of the second main heater to a temperature lower than the melting point of the target substance while setting each of the temperature of the first main heater and the temperature of the first sub-heater to a temperature higher than the melting point of the target substance.

14. The target supply device according to claim 13,
wherein, in the temperature lowering control, the temperature control processor maintains, during a second predetermined period, the temperature of the intermediate portion heater in a second temperature range lower than the melting point of the target substance while maintaining the temperature of the first main heater, the temperature of the second main heater, and the temperature of the first sub-heater in a first temperature range higher than the melting point of the target substance, and then, during a third predetermined period, maintains the temperature of the second main heater in the second temperature range while maintaining the temperature of the first main heater and the temperature of the first sub-heater in the first temperature range.

15. An extreme ultraviolet light generation apparatus comprising:
a chamber in which a target substance supplied to an internal space thereof is irradiated with laser light to generate extreme ultraviolet light; and
a target supply device configured to supply the target substance into the chamber;
the target supply device including:
a tank main body portion configured to contain the target substance;
an output portion configured to output the target substance;
an intermediate portion located between the tank main body portion and the output portion;
a first main heater configured to heat the tank main body portion;
a first sub-heater configured to heat the output portion;
an intermediate portion heater configured to heat the intermediate portion; and
a temperature control processor configured to perform temperature lowering control of the first main heater, the first sub-heater, and the intermediate portion heater after output of the target substance is stopped,
the temperature control processor setting, in the temperature lowering control, a temperature of the intermediate portion heater to a temperature lower than a melting point of the target substance while setting each of a temperature of the first main heater and a temperature of the first sub-heater to a temperature higher than the melting point of the target substance.

16. An electronic device manufacturing method, comprising:
generating extreme ultraviolet light using an extreme ultraviolet light generation apparatus;
outputting the extreme ultraviolet light to an exposure apparatus; and
exposing a photosensitive substrate to the extreme ultraviolet light in the exposure apparatus to manufacture an electronic device,
the extreme ultraviolet light generation apparatus including:
a chamber in which a target substance supplied to an internal space thereof is irradiated with laser light to generate the extreme ultraviolet light; and
a target supply device configured to supply the target substance into the chamber,
the target supply device including:
a tank main body portion configured to contain the target substance;
an output portion configured to output the target substance;
an intermediate portion located between the tank main body portion and the output portion;
a first main heater configured to heat the tank main body portion;
a first sub-heater configured to heat the output portion;
an intermediate portion heater configured to heat the intermediate portion; and
a temperature control processor configured to perform temperature lowering control of the first main heater, the first sub-heater, and the intermediate portion heater after output of the target substance is stopped, and
the temperature control processor setting, in the control, a temperature lowering temperature of the intermediate portion heater to a temperature lower than a melting point of the target substance while setting each of a temperature of the first main heater and a temperature of the first sub-heater to a temperature higher than the melting point of the target substance.
